(19) United States
(12) Patent Application Publication
(10) Pub. No.: US 2006/0209706 A1
(43) Pub. Date: Sep. 21, 2006

(54) Intercepting mobile telephone communications

(76) Inventors: Robert Geoffrey Ward, Colorado Springs, CO (US); Andrew McArthur, Colorado Springs, CO (US)

Correspondence Address: AGILENT TECHNOLOGIES, INC.;Legal Department, DL 429, Intellectual Property Administration, P.O. Box 7599, Loveland, CO, 80537-0599, US

(21) Appl. No.: 11/083,928

(22) Filed: Mar. 21, 2005

(51) Int. Cl. G01R 31/08; H04L 12/28; H04Q 7/00

(52) U.S. Cl. 370/252; 370/329; 370/395.1

(57) ABSTRACT

Monitoring mobile telephone signaling carried by an ATM network to determine channels of interest. ATM cells of the ATM network are intercepted to monitor a UMTS terrestrial radio access network (UTRAN). The intercepted ATM cells are automatically analyzed to obtain a correspondence between a static Node B channel and a different private channel of the ATM network that is used to carry traffic to/from the Node B. The correspondence and other correspondences may be stored in a lookup table. A Node B's VPI.VCI, a VPI.VCI of a connected number may be extracted from a connection message. A call reference may be extracted from the connection message and stored in association with the correspondence. A connection breakdown message may be detected and, based on the release message matching the previously stored call reference, the stored correspondence that is associated with the call reference may be deleted.

### BACKGROUND

Monitoring traffic for a Node B is important for deploying, testing, and monitoring a mobile network. A Radio Network Controller controlling a Node B communicates with the Node B via a UNI link to a private ATM network and then to a UNI link to the node B. When a UNI is used to connect the RNC in to the ATM network it is possible to monitor traffic for a Node B because the UNI has an identifiable channel. However, when the RNC access the ATM network directly using a PNNI link, then it is impossible to monitor traffic for the Node B at the RNC because the identity of the ATM channel used to carry traffic to the Node B (via its UNI) is unknown. There is a need to monitor traffic for a Node B at an RNC when the RNC connects with the ATM network directly using a PNNI.

### BRIEF DESCRIPTION OF THE DRAWINGS

FIG. 1 shows part of a mobile network in the related art.

FIG. 2 shows part of a mobile network where an RNC uses a PNNI to interface with the private ATM network.

FIG. 3 shows a sequence of messages between the RNC and the PNNI that setup of a PVCC (Permanent Virtual Channel Connection).

FIG. 4 shows a process for using the connect sequence to facilitate monitoring a Node B's traffic on a PNNI.

FIG. 5 shows a system in which the process of FIG. 4 may be implemented.

FIG. 6 shows a functional diagram of test equipment using a Node B's PNNI VPI.VCI in a lookup table.

FIG. 7 shows a more detailed system diagram.

### DETAILED DESCRIPTION OF THE PREFERRED EMBODIMENTS

Some relevant acronyms are well known in the art of wireless networks but are repeated here for the reader's convenience. The term “UMTS” refers to the Universal Mobile Telecommunications System, which is a known industry standard for a type of mobile telecommunications system. The term “CN” refers to a core network. The term “Node B” refers to a UMTS base station or physical tower. The term “RNC” refers to a radio network controller. The term “lub” refers to an interface or link between a Node B and an RNC. The term “lur” refers to an interface or link between an RNC and another RNC. The term “lu” refers to an interface or link between an RNC and a CN. The term “UTRAN” refers to a UMTS terrestrial radio access network, which is an actual implementation of a UTMTS. The term “UNI” refers to a User Network Interface. The term “PNNI” refers to a Network to Network Interface. The term “PVCC” refers to a Permanent Virtual Channel Connection. The term “HEC” refers to Header Error Control. The term “SVC” refers to Switched Virtual Circuit.

Additionally, the term “VPI” (virtual path indicator) refers to an 8-bit or 12 bit field in the header of an ATM cell. The term “VCI” (virtual channel indicator) refers to a 16-bit field in the header of an ATM cell. ATM switches use the VPI/VCI fields to identify the next VCL (virtual channel link) that a cell needs to transit on its way to its final destination. In other words, the VCI together with the VPI is used to identify the next destination of a cell as it passes through a series of ATM switches on its way to its destination. ATM switches use the VPI/NCI fields to identify the next network VCL (virtual channel link) that an ATM cell needs to transit on its way to its final destination. The terms “user plane” and “control plane” are well known in the art and are discussed in the IEC publication mentioned below. They generally refer to user-oriented packets (user plane) and control or system oriented packets (control plane).

There is a need to monitor mobile networks. Presently, most mobile networks are Second Generation (“2G”) networks. Third Generation (“3G”) mobile networks are in development. Like 2G networks, 3G networks have cell towers called Node Bs. The RNC that controls a cell tower uses an ATM network. From the RNC data is communicated to multiple Node Bs. One RNC may control many, even several hundred, Node Bs. The RNC may be at one location, and Node Bs controlled by the RNC may be at remote sites such as at the top of a building, on top of a remote hill, etc. Often, instead of building an ATM network from scratch, he operator or mobile provider will use another entity's ATM network. This ATM network is sometimes called a private ATM network. The switches within the private ATM network use PNNI to cooperate. PNNI is a protocol is for distributing topology information between the ATM switches of the private network and is used to compute paths through the private network. At the edges of the private ATM network a customer such as a mobile provider or other user connects to the private ATM network, tells the private ATM network what is needed, etc.

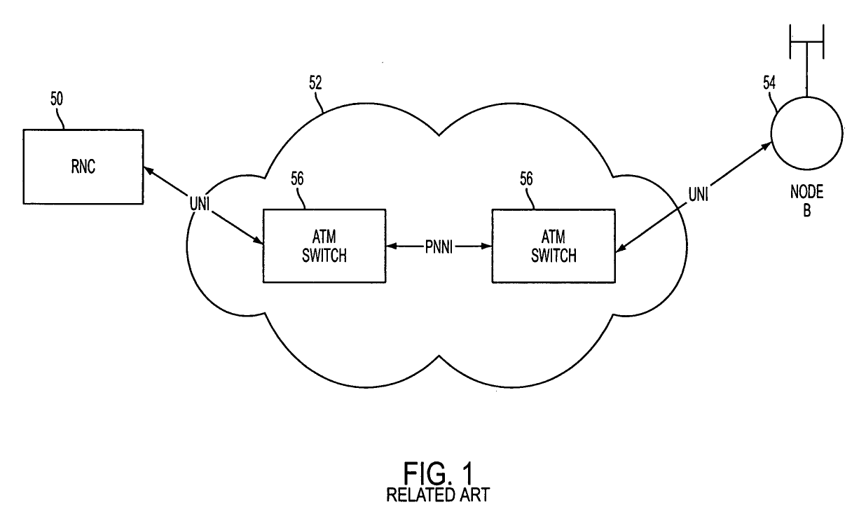

FIG. 1 shows part of a mobile network in the related art. Some mobile networks use private networks to carry mobile telephone communications. In FIG. 1, the RNC 50 of a mobile network uses a private ATM network 52 to communicate with a Node B 54. The private ATM network 52 has ATM switches 56 which communicate with each other using PNNI. Third Generation mobile networks have used the UNI protocol at the edges of the private ATM network 52 to send/receive communications through the private ATM network 52.

An ATM identifies a channel using a VPI and a VCI. For example, the Node Bs associated with a particular RNC may each have their own public VPI and VCI. However, the private ATM network 52 will use different private VPIs and VCIs to route cells between then RNC 50 and the Node B 54. Usually, a customer or subscriber, such as a mobile telephone provider, will not have access to the internal PNNI routing information of the private ATM network 52. For instance, a user will not know the private VPIs and VCIs used for routing within the private ATM network 52.

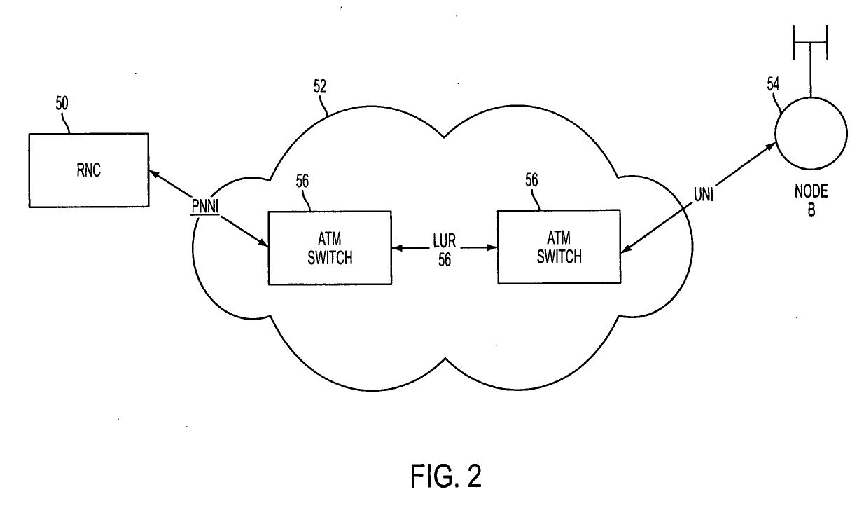

FIG. 2 shows part of a mobile network where an RNC uses a PNNI to interface with the private ATM network 52. In this case, because the RNC is using a PNNI rather than a UNI at the edge of the private ATM network. In effect, the RNC becomes a node of the ATM network. As explained below, this makes it difficult to monitor traffic for a particular Node B at the RNC because the VPI and VCI of the Node B and its UNI are not known. More specifically, it is desirable to be able to filter out the traffic on the PNNI that is for a particular Node B. However, when the VPI.VCI of the Node B is not known, it is difficult or impossible to identify or select out ATM cells that are only carrying data to/from the Node B.

When the RNC uses a PNNI, it in effect becomes part of the private ATM network. Within the RNC, communications are sent to the static or known VPI.VCI of the Node B. However, the traffic for the Node B is difficult to monitor at the RNC because the private ATM network will use its own internal VPI and VCI to internally route the Node B's traffic. In other words, the user at the RNC knows the VPI.VCI of the Node B, but when the equipment manufacturer allows direct access to an ATM edge switch via a PNNI link, the RNC effectively becomes part of the private ATM network and a network monitor only has access to the PNNI.

One technique is to monitor the PNNI signaling messages that go across the PNNI at a monitoring point to determine the mapping of the UNI VPI.VCI to the PNNI VPI.VCI at the monitoring point.

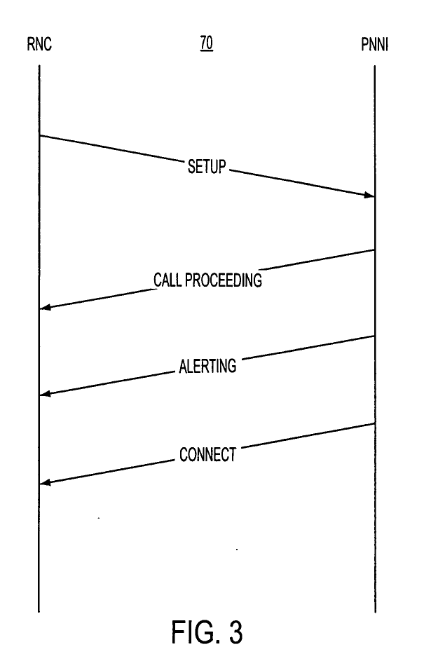

Although the PNNI protocol is a highly complex protocol, it is possible to facilitate monitoring of the traffic for a Node B at the PNNI of an RNC. FIG. 3 shows a sequence of messages 70 between the RNC and the PNNI that setup of a PVCC (Permanent Virtual Channel Connection). The RNC sends a “setup” message. The PNNI responds with a “call proceeding” message, an “alerting” message, and a “connect” message.

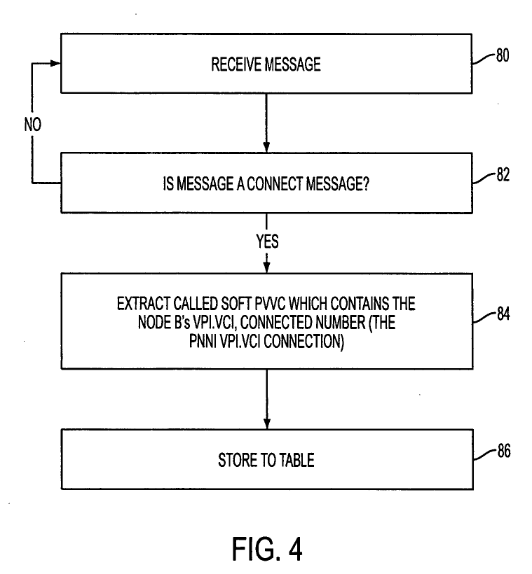

FIG. 4 shows a process for using the connect sequence to facilitate monitoring a Node B's traffic on a PNNI. First, a message is received 80. The message is analyzed. A message can be identified as a “connect” message, for example, if its VPI.VCI=0.5, its “Message Type” is “CONNECT” as defined by Q.2931. If the message in 82 a connect message then certain information is extracted 84. The extraction information can include the UNI/Node B's VPI.VCI and the VPI.VCI of the PNNI connection at the point of monitoring. The Node B's VPI.VCI is extracted from the soft PVVC. The Node B's VPI.VCI and the private network's VPI.VCI are stored 86 in a table.

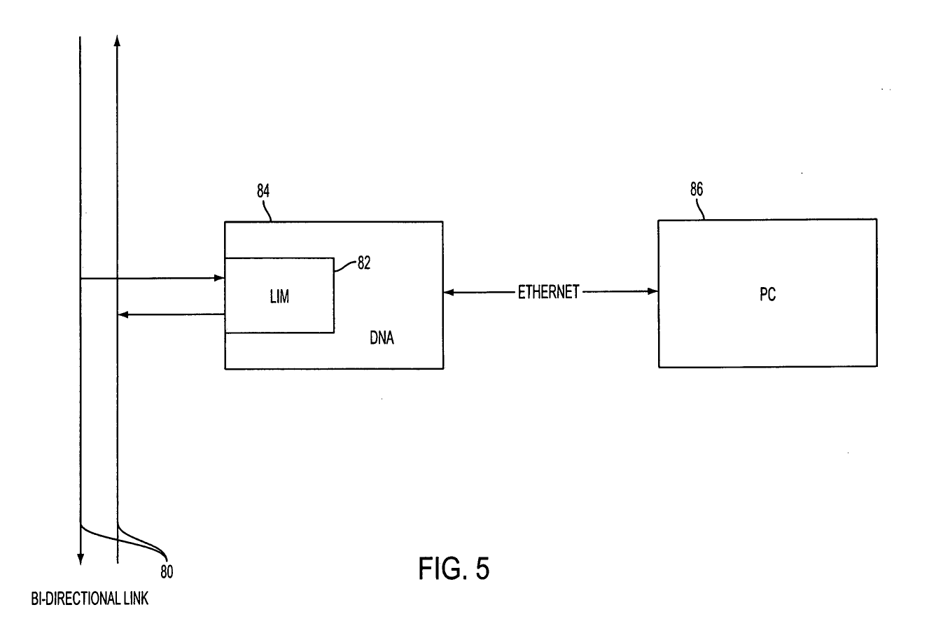

FIG. 5 shows a system in which the process of FIG. 4 may be implemented. Signals are received on the PNNI's bi-directional link 80. A Line Interface Module 82 in a Distributed Network Analyzer (DNA) 84 receives the signals and converts the format of the LIM's interface (e.g. OC-3, fiber, T1 copper, etc.) into a data stream. The DNA 84 captures the relevant data, which is passed to a PC 86, which acts as a test data accumulator, analysis station, etc.

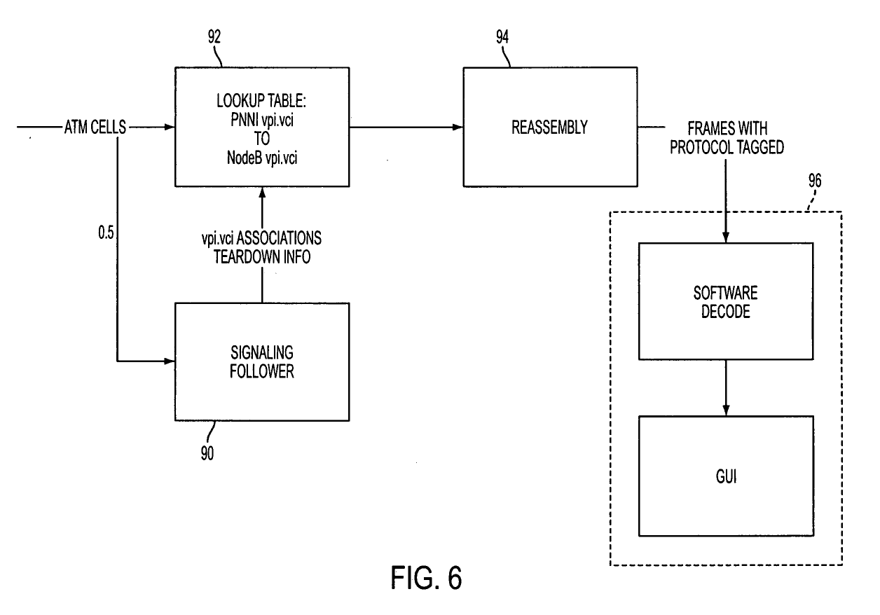

FIG. 6 shows a functional diagram of test equipment using a Node B's PNNI VPI.VCI in a lookup table. ATM cells from the PNNI are received. Cells with VPI.VCI=0.5 are passed to a signaling follower 90. If the signaling follower 90 detects a “connect” message, then the PNNI:VPI.VCI and associated UNI/Node B:VPI.VCI are added to lookup table 92. If the signalling follower 90 detects a “disconnect” message to tear down a connection, then lookup table 92 is instructed to drop the corresponding VPI.VCI association entry. ATM cells from the PNNI that are not 0.5 are passed to the lookup table to convert the VPI.VCI to the VPI.VCI at the UNI. Translated cells are passed to a reassembly unit 94 for reassembly into frames, where they are tagged and passed to a test station or PC 96. Frame protocols can include, but are not limited to, NBAP, ALCAP, RANAP, RNSAP, RRC, etc.

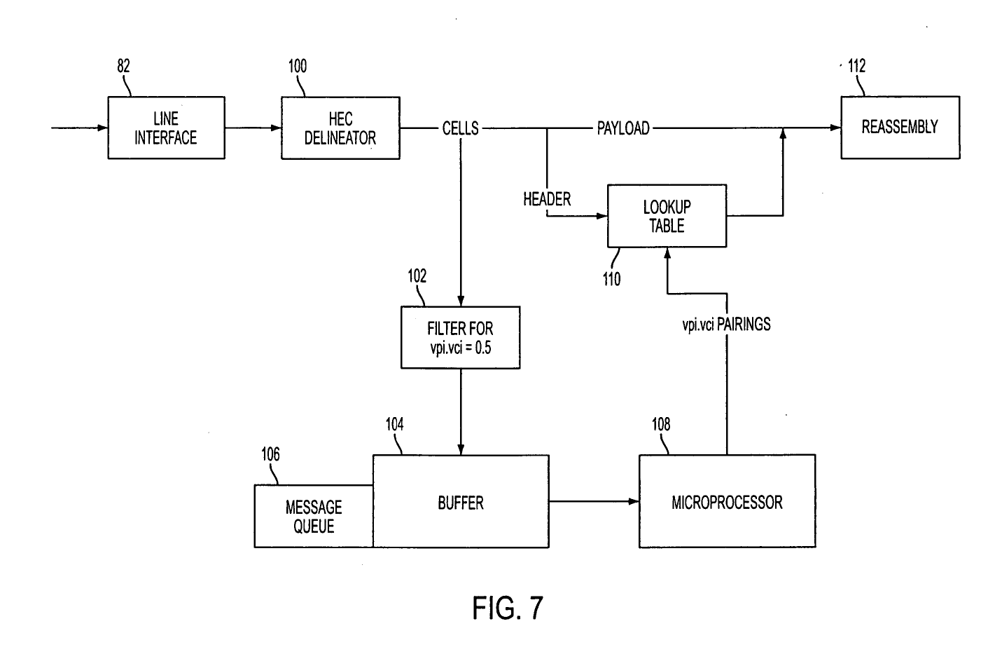

FIG. 7 shows a more detailed diagram. The line interface module (LIM) 82 receives signal data from an RNC's PNNI. A Header Error Control (HEC) delineator delineates data from the LIM 82 into ATM cells. Cells with VPI.VIC=0.5 are filtered by a filter 102 and passed to a buffer 104. It may be that signaling cells are temporarily input at a rate faster than microprocessor 108 can handle. A message queue 106 administers buffer 104 and ensures that all signaling messages are processed in the order that they arrived. Microprocessor 108 updates lookup table 110 with pairings: UNI/Node B VPI.VCI, PNNI VPI.VCI. A user wants to look at traffic for the Node B, so the lookup table is used to identify traffic for the Node B. More specifically, reassembly unit 112 reassembles the cell payloads using the lookup table 110. In one embodiment, the lookup table comprises a Content Addressable Memory (CAM) and a Random Access Memory (RAM). The VPI.VCI is presented to the CAM which returns an address unique to the VPI.VCI. This address is then input to the RAM which returns the VPI.VCI at the UNI.

Embodiments discussed above relate to monitoring mobile telephone signaling carried by an ATM network to determine channels of interest. ATM cells of the ATM network are intercepted to monitor a UMTS terrestrial radio access network (UTRAN). The intercepted ATM cells are automatically analyzed to obtain a correspondence between a static Node B channel and a different private channel of the ATM network that is used to carry traffic to/from the Node B. The correspondence and other correspondences may be stored in a lookup table. A Node B's VPI.VCI, a VPI.VCI of a connected number may be extracted from a connection message. A call reference may be extracted from the connection message and stored in association with the correspondence. A connection breakdown message may be detected and, based on the release message matching the previously stored call reference, the stored correspondence that is associated with the call reference may be deleted.

The many features and advantages of the invention are apparent from the detailed specification and, thus, it is intended by the appended claims to cover all such features and advantages of the invention that fall within the true spirit and scope of the invention. Further, since numerous modifications and changes will readily occur to those skilled in the art, it is not desired to limit the invention to the exact construction and operation illustrated and described, and accordingly all suitable modifications and equivalents may be resorted to, falling within the scope of the invention.

What is claimed is:

1. A method of monitoring mobile telephone signaling carried by an ATM network to determine channels of interest, comprising:
receiving ATM cells of the ATM network intercepted to monitor a UMTS terrestrial radio access network (UTRAN);
automatically analyzing the intercepted ATM cells to obtain a correspondence between a static Node B channel and a different private channel of the ATM network that is used to carry traffic to/from the Node B; and
storing the correspondence.

2. A method according to claim 1, wherein the analyzing comprises detecting connection messages and extracting from a connection message a Node B's VPI.VCI, a VPI.VCI of a connected number.

3. A method according claim 2, further comprising extracting from the connection message a call reference and storing the call reference in association with the correspondence.

4. A method according to claim 3, further comprising detecting a release message for breaking down a connection and, based on the release message matching the previously stored call reference, deleting the stored correspondence that is associated with the call reference.

5. A computing apparatus configured to perform a method according to claim 1.

6. A computing apparatus according to claim 5, wherein the apparatus comprises a mobile network monitoring station.

7. A computer-readable recording medium storing information to enable a computer to perform a method according to claim 1.

8. A method of associating frames with Node Bs, the method comprising:
receiving ATM cells on the PNNI of an RNC communicating with a Node B via a private ATM network, where the node B connects to the private ATM network using a UNI; and
extracting from the received ATM cells associations between Node B's and respective VPI.VCIs in the private ATM network when a connection is being formed between the RNC and a Node B.

9. A method according to claim 8, further comprising:
storing the associations in a table;
reassembling the received ATM cells into mobile telephony frames; and
tagging reassembled mobile telephony frames with a protocol according to matching respective VPI.VCIs in the table.

10. A method according to claim 8, further comprising extracting from the received ATM cells teardown information and using the tear down information to clear associations in the table that correspond to the teardown information.

11. A method according to claim 8, wherein the ATM cells that have associations extracted therefrom are selected based on a determination that their ATM channel is 0.5.

12. A method according to claim 8, further comprising using the table to automatically monitor traffic for an RNC and/or Node Bs controlled by the RNC.

13. An computing apparatus configured to perform a method according to claim 8.

14. An computing apparatus configured to perform a method according to claim 9.

15. A computer-readable storage medium storing information to enable a computer to perform a method according to claim 8.

16. A computer-readable storage medium storing information to enable a computer to perform a method according to claim 9.

17. A network monitoring device comprising:
a line interface module for receiving signals from a PNNI link connecting an RNC with a private ATM network;
a processor configured to: analyze ATM cells derived from the signals received by the line interface module, detect connect messages and extract therefrom VPI.VCIs of UNIs connecting the ATM network and respective Node Bs and also extract VPI.VCIs of channels in the private ATM network for carrying ATM cells to the Node Bs; and
a memory configured to store the information extracted from the connect messages.
